(19) United States
(12) Patent Application Publication
(10) Pub. No.: US 2024/0162829 A1
(43) Pub. Date: May 16, 2024

(54) POWER CONVERSION DEVICE

(71) Applicants: Mitsubishi Electric Corporation, Tokyo (JP); Toshiba Mitsubishi-Electric Industrial Systems Corporation, Tokyo (JP)

(72) Inventors: Yasushige MUKUNOKI, Chiyoda-ku, Tokyo (JP); Takeshi HORIGUCHI, Chiyoda-ku, Tokyo (JP); Hiroki SHIGETA, Chuo-ku, Tokyo (JP)

(73) Assignees: Mitsubishi Electric Corporation, Tokyo (JP); Toshiba Mitsubishi-Electric Industrial Systems Corporation, Tokyo (JP)

(21) Appl. No.: 18/283,822

(22) PCT Filed: Apr. 1, 2021
(86) PCT No.: PCT/JP2021/014206

§ 371 Date: Sep. 25, 2023

(51) Int. Cl. H02M 7/00; H05K 7/20

(52) U.S. Cl. CPC H02M 7/003; H05K 7/209

(57) ABSTRACT

A power conversion device includes a housing, a door, a power converter, and a movable portion. Housing includes an opening and an internal space. Door is connected to housing. Power converter is disposed in internal space with a gap from housing. Movable portion is disposed in internal space. Movable portion is configured to be detachable with respect to power converter. Door is configured to be switchable between an open state in which opening is open and a closed state in which opening (OP) is closed. Power converter is configured to be grounded via movable portion in the open state of door. Power converter is configured to be disposed with a gap from movable portion in the closed state of door.

### TECHNICAL FIELD

The present disclosure relates to a power conversion device.

### BACKGROUND ART

In a power conversion device such as a power source-less power supply device, a power converter is housed in an internal space of a grounded housing. The power converter is configured to convert power supplied from the outside by a switching operation. In addition, a door of the power conversion device is configured to be switchable between a closed state in which the internal space is closed and an open state in which the internal space is open.

For example, Japanese Patent No. 4320981 (PTL 1) discloses a door handle device for an electric equipment panel configured to be switched between an open state and a closed state of a door. The electric equipment panel includes a housing, a door (door), and a movable portion (door handle). The movable portion is configured to be electrically connected to the housing in the closed state of the door. Therefore, in the closed state, the movable portion is grounded. In addition, the movable portion is configured to be electrically shut off from the housing in the open state of the door.

### CITATION LIST

### Patent Literature

PTL 1: Japanese Patent No. 4320981

### SUMMARY OF INVENTION

### Technical Problem

When a worker performs work on the power converter in the open state of the door, the power converter needs to be grounded by being electrically connected to the housing for the safety of the worker. On the other hand, when the power converter is always grounded, there is a problem that a high-frequency noise current continues to flow from the power converter to the ground. A propagation path of the high-frequency noise current to the ground is the housing. In addition, regulations are imposed in various countries on a high-frequency noise current flowing outside. In order to suppress the high-frequency noise current from flowing outside, it is preferable that the power converter be electrically shut off from the grounded housing. In the closed state of the door, the worker does not perform work on the power converter in the internal space of the housing.

In the door handle device of the electric power equipment panel described in the above document, the movable portion is grounded in the closed state of the door, and the movable portion is electrically shut off from the housing in the open state of the door. Therefore, if the door handle device of the power device board described in the above literature is applied to the power conversion device in such a manner that the power converter is disposed in the internal space of the housing and is connected to the movable portion, the power converter is grounded in the closed state of the door and is electrically shut off from the housing in the open state of the door. Therefore, the power converter cannot be grounded in the open state of the door, and the power converter cannot be electrically shut off in the closed state of the door.

The present disclosure has been made in view of the above issue, and an object of the present disclosure is to provide a power conversion device in which a power converter can be grounded in an open state of a door and be electrically shut off in a closed state of the door.

### Solution to Problem

A power conversion device of the present disclosure includes a housing, a door, a power converter, and a movable portion. The housing includes an opening and an internal space. The internal space communicates with the opening. The door is connected to the housing. The power converter is disposed in the internal space with a gap from the housing. The movable portion is disposed in the internal space. The movable portion is configured to be detachable from the power converter. The door is configured to be switchable between an open state in which the opening is open and a closed state in which the opening is closed. The power converter is configured to be grounded via the movable portion in the open state of the door. The power converter is configured to be disposed with a gap from the movable portion in the closed state of the door.

### Advantageous Effects of Invention

According to the power conversion device of the present disclosure, the movable portion is configured to be detachable with respect to the power converter. The power converter is configured to be grounded via the movable portion in the open state of the door. Therefore, the power converter can be grounded in the open state of the door. The power converter is configured to be disposed with a gap from the movable portion in the closed state of the door. Therefore, the power converter can be electrically shut off in the closed state of the door.

### BRIEF DESCRIPTION OF DRAWINGS

FIG. 1 is a cross-sectional view schematically illustrating a configuration, in an open state, of a power conversion device according to a first embodiment.

FIG. 2 is a cross-sectional view schematically illustrating the configuration, in a closed state, of the power conversion device according to the first embodiment.

FIG. 3 is a cross-sectional view schematically illustrating the configuration, in the open state, of the power conversion device according to a variation of the first embodiment.

FIG. 4 is a cross-sectional view schematically illustrating a configuration, in an open state, of a power conversion device according to a second embodiment.

FIG. 5 is a perspective view schematically illustrating the configuration, in the open state, of the power conversion device according to the second embodiment.

FIG. 6 is a perspective view schematically illustrating the configuration, in a closed state, of the power conversion device according to the second embodiment.

FIG. 7 is a perspective view schematically illustrating the configuration, in the open state, of the power conversion device according to a variation of the second embodiment.

FIG. 8 is a perspective view schematically illustrating a configuration, in an open state, of a power conversion device according to a third embodiment.

FIG. 9 is a perspective view schematically illustrating the configuration, in a closed state, of the power conversion device according to the third embodiment.

FIG. 10 is a perspective view schematically illustrating a configuration, in an open state, of a power conversion device according to a fourth embodiment.

FIG. 11 is a perspective view schematically illustrating the configuration, in a closed state, of the power conversion device according to the fourth embodiment.

### DESCRIPTION OF EMBODIMENTS

Hereinafter, embodiments will be described with reference to the drawings. In the following description, the same or corresponding parts are denoted by the same reference signs, and redundant description will not be repeated.

### First Embodiment

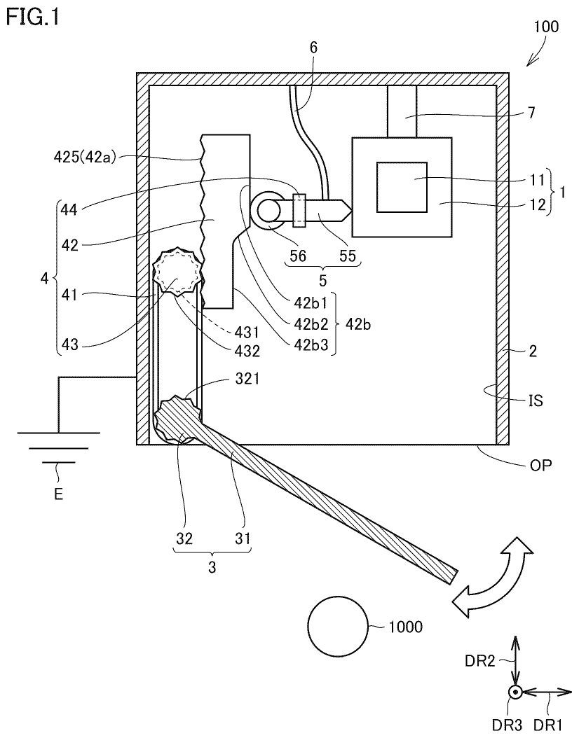

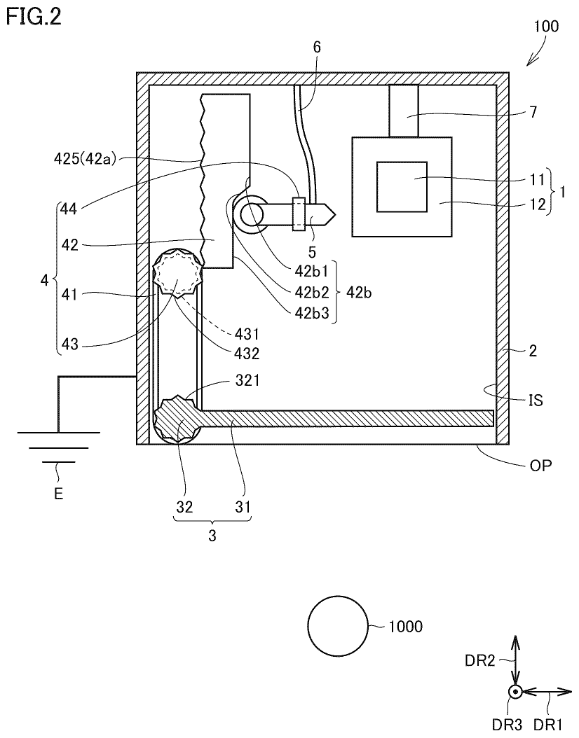

With reference to FIGS. 1 and 2, a configuration of a power conversion device 100 according to a first embodiment will be described. Power conversion device 100 is included in, for example, an uninterruptible power supply (UPS). As illustrated in FIG. 1, power conversion device 100 is configured to be workable by a worker 1000. Power conversion device 100 includes a power converter 1, a housing 2, a door 3, a transmission portion 4, and a movable portion 5. The power conversion device may further include a ground wire 6 and a fixing portion 7.

Power converter 1 is disposed in an internal space IS with a gap from housing 2. In the present embodiment, the gap between power converter 1 and housing 2 is a gap with which power converter 1 and housing 2 are electrically shut off from each other. Preferably, the gap between power converter 1 and housing 2 is a gap with which a high-frequency AC voltage is electrically shut off. A frequency of the high-frequency alternating current is, for example, greater than or equal to 150 kHz and less than or equal to 1 GHz.

Power converter 1 is fixed to housing 2 with a fixing portion 7. Fixing portion 7 is, for example, an insulating member such as an insulating resin bolt. Fixing portion 7 is configured to insulate DC voltage. Fixing portion 7 is configured to insulate, for example, a high-frequency alternating current.

Power converter 1 includes a semiconductor element 11 and a metal member 12. Power converter 1 is configured to convert power by semiconductor element 11. Semiconductor element 11 is, for example, a diode made of silicon (Si). Semiconductor element 11 is, for example, a metal oxide semiconductor field effect transistor (MOSFET), an insulated gate bipolar transistor (IGBT), or a thyristor. Semiconductor element 11 may be a wide band gap semiconductor.

Metal member 12 is connected to semiconductor element 11. Metal member 12 is a cooler. Metal member 12 is, for example, an air-cooled heat sink. Metal member 12 may be a water-cooled heat sink. When metal member 12 is a heat sink, a material of metal member 12 is, for example, aluminum (Al). The material of metal member 12 is not limited to aluminum (Al).

Housing 2 includes an opening OP and internal space IS. In internal space IS of housing 2, there are disposed power converter 1, transmission portion 4, movable portion 5, and ground wire 6. Internal space IS communicates with opening OP. A material of housing 2 is metal. A surface of housing 2 may be coated to suppress corrosion. An outer shape of housing 2 is a rectangular parallelepiped shape.

Housing 2 is grounded. In the present embodiment, housing 2 is electrically connected to a ground E.

Door 3 is connected to housing 2. Door 3 is connected to, for example, a bottom portion of housing 2. As illustrated in FIGS. 1 and 2, door 3 is configured to be switchable between an open state in which opening OP is open and a state in which opening OP is closed. Door 3 is configured to be switchable between the open state of door 3 and the closed state of door 3 by being rotated with respect to housing 2. Therefore, door 3 is configured as a so-called hinged door.

Door 3 includes a main body portion 31 and a shaft portion 32. As illustrated in FIG. 2, main body portion 31 is configured to be able to close opening OP. Main body portion 31 is configured to be rotated by rotation of shaft portion 32. Shaft portion 32 is configured as a rotation axis of a rotational movement of door 3. Shaft portion 32 includes a first gear part 321. First gear part 321 of shaft portion 32 is engaged with a connection portion 41, to be described later, of transmission portion 4.

In the present embodiment, a Z-axis direction DR3 is a direction along the rotation axis of door 3. A Y-axis direction DR2 is a depth direction of housing 2. An X-axis direction DR1 is a direction intersecting with each of the Y-axis direction DR2 and the Z-axis direction DR3.

Transmission portion 4 is connected to housing 2. Transmission portion 4 is connected to, for example, the bottom portion of housing 2. Transmission portion 4 is connected to door 3.

Transmission portion 4 is configured to transmit the rotational movement of door 3 to movable portion 5 so as to attach and detach movable portion 5 to and from power converter 1. Transmission portion 4 is configured to be activated by the rotational movement of door 3.

Preferably, transmission portion 4 is configured to convert the rotational movement of door 3 into a linear movement. Transmission portion 4 is configured to transmit the linear movement to movable portion 5, thereby linearly moving movable portion 5. In the present embodiment, transmission portion 4 is configured to convert the rotational movement of door 3 into a linear movement along the Y-axis direction DR2. Transmission portion 4 is configured to transmit a linear movement along Y-axis direction DR2 to movable portion 5, thereby linearly moving movable portion 5 along the X-axis direction DR1.

Specifically, transmission portion 4 includes connection portion 41, a moving portion 42, a driven portion 43, and a restriction portion 44. Connection portion 41 is, for example, a chain. Moving portion 42 includes, for example, a rack gear having a second gear part 425. Driven portion 43 includes a third gear part 431 and a fourth gear part 432. Third gear part 431 and fourth gear part 432 are disposed to be shifted from each other along the Z-axis direction DR3. Driven portion 43 includes, for example, a pinion gear having third gear part 431. Driven portion 43 is configured to be rotatable. A rotation axis of driven portion 43 extends along the Z-axis direction DR3.

Connection portion 41 is connected to shaft portion 32. Connection portion 41 is engaged with first gear part 321 of shaft portion 32. Connection portion 41 is engaged with third gear part 431 of driven portion 43. More specifically, engaged portions between the chains of connection portion 41 mesh with respective ones of first gear part 321 and third gear part 431. Therefore, connection portion 41 is configured to be able to transmit the rotational movement of door 3 to driven portion 43. Therefore, driven portion 43 is configured to rotate when the rotational movement of door 3 is transmitted by connection portion 41.

Second gear part 425 of moving portion 42 is engaged with fourth gear part 432 of driven portion 43. Therefore, the rotation of driven portion 43 is transmitted to moving portion 42. Moving portion 42 is configured to linearly move by the rotational movement of driven portion 43. Therefore, moving portion 42 is configured to linearly move movable portion 5 by the rotational movement transmitted by connection portion 41.

In the present embodiment, moving portion 42 is a plane cam. Specifically, moving portion 42 is a linear advancement plate cam that is a type of plane cam. Movable portion 5 is configured as a cam follower for moving portion 42.

Moving portion 42 includes a first surface 42a and a second surface 42b. First surface 42a includes second gear part 425. Second gear part 425 is engaged with fourth gear part 432 of driven portion 43. Second surface 42b is a cam surface. Second surface 42b is opposed to first surface 42a. Second surface 42b is in contact with movable portion 5. Second surface 42b includes a first flat surface portion 42b1, a slope portion 42b2, and a second flat surface portion 42b3. Slope portion 42b2 connects first flat surface portion 42b1 and second flat surface portion 42b3. A thickness between first surface 42a and first flat surface portion 42b1 of moving portion 42 is larger than a thickness between first surface 42a and second flat surface portion 42b3 of moving portion 42.

Restriction portion 44 is fixed to housing 2. Restriction portion 44 is fixed to, for example, a bottom surface of housing 2. Restriction portion 44 sandwiches movable portion 5 along the Y-axis direction DR2. A movement of movable portion 5 along the Y-axis direction DR2 is restricted by restriction portion 44. Movable portion 5 is configured to be movable along the X-axis direction DR1.

Movable portion 5 is disposed in internal space IS. Movable portion 5 is connected to housing 2. A material of movable portion 5 is metal. In the present embodiment, movable portion 5 is electrically connected to housing 2 with ground wire 6. Therefore, movable portion 5 is grounded via housing 2 and ground wire 6. Note that movable portion 5 may be grounded by being directly connected to ground E without ground wire 6 interposed therebetween.

As illustrated in FIGS. 1 and 2, movable portion 5 is configured to be detachable with respect to power converter 1. More specifically, movable portion 5 is configured to be detachable with respect to metal member 12 of power converter 1. Movable portion 5 is configured to be detachable with respect to power conversion device 100 along the X-axis direction DR1. Movable portion 5 is configured to come into contact with power converter 1 to electrically connect power converter 1 to housing 2.

Movable portion 5 is in contact with transmission portion 4. In the present embodiment, movable portion 5 includes a contact portion 55 and a rotation portion 56. Contact portion 55 is configured to be able to come into contact with power converter 1. Rotation portion 56 is configured to rotate in accordance with movement of moving portion 42.

Next, a configuration of power conversion device 100 will be described in detail while comparing FIG. 1 illustrating the open state of door 3 and FIG. 2 illustrating the closed state of door 3 with each other.

As illustrated in FIG. 1, power converter 1 is configured to be grounded via movable portion 5 in the open state of door 3. The open state of door 3 is a state in which opening OP is sufficiently opened so that worker 1000 can access internal space IS of housing 2. Therefore, in the open state of door 3, worker 1000 can perform work on power converter 1, transmission portion 4, and movable portion 5 disposed in internal space IS of housing 2. Movable portion 5 is configured to be in contact with first flat surface portion 42b1 of second surface 42b of moving portion 42 in the open state of door 3.

On the other hand, as illustrated in FIG. 2, power converter 1 is configured to be disposed with a gap from movable portion 5 in the closed state of door 3. The closed state of door 3 is a state in which opening OP is closed so that worker 1000 cannot access internal space IS of housing 2. Therefore, in the closed state of door 3, worker 1000 cannot perform work on power converter 1, transmission portion 4, or movable portion 5 disposed in internal space IS of housing 2.

The gap between power converter 1 and movable portion 5 in the closed state of door 3 is a gap with which power converter 1 and movable portion 5 are electrically shut off from each other. Preferably, the gap between power converter 1 and movable portion 5 is a gap with which a high-frequency AC voltage is electrically shut off. Power converter 1 is configured to be electrically shut off from movable portion 5 in the closed state of door 3. Power converter 1 is disposed with a gap from each of housing 2 and movable portion 5 in the closed state of door 3. Preferably, power converter 1 is shut off from each of housing 2 and movable portion 5 in the closed state of door 3. Movable portion 5 is configured to be in contact with second flat surface portion 42b3 of second surface 42b of moving portion 42 in the closed state of door 3.

Next, an operation of power conversion device 100 according to the first embodiment will be described.

When door 3 is switched from the open state of door 3 to the closed state of door 3, transmission portion 4 transmits the rotational movement of door 3 to movable portion 5, so that movable portion 5 moves to a deep side of housing 2 along the Y-axis direction DR2. As a result, movable portion 5 comes into contact first flat surface portion 42b1, slope portion 42b2, and second flat surface portion 42b3 in this order. Therefore, movable portion 5 moves from a first flat surface portion 42b1 side to a second flat surface portion 42b3 side along the X-axis direction DR1. As a result, movable portion 5 comes apart from power converter 1. In other words, power converter 1 is electrically shut off from movable portion 5.

When door 3 is switched from the closed state of door 3 to the open state of door 3, transmission portion 4 transmits the rotational movement of door 3 to movable portion 5, so that movable portion 5 moves to an opening OP side (near side) along the Y-axis direction DR2. As a result, movable portion 5 comes into contact with second flat surface portion 42b3, slope portion 42b2, and first flat surface portion 42b1 in this order. Therefore, movable portion 5 moves from the second flat surface portion 42b3 side to the first flat surface portion 42b1 side along the X-axis direction DR1. As a result, movable portion 5 comes into contact with power converter 1. Thus, power converter 1 is grounded via movable portion 5.

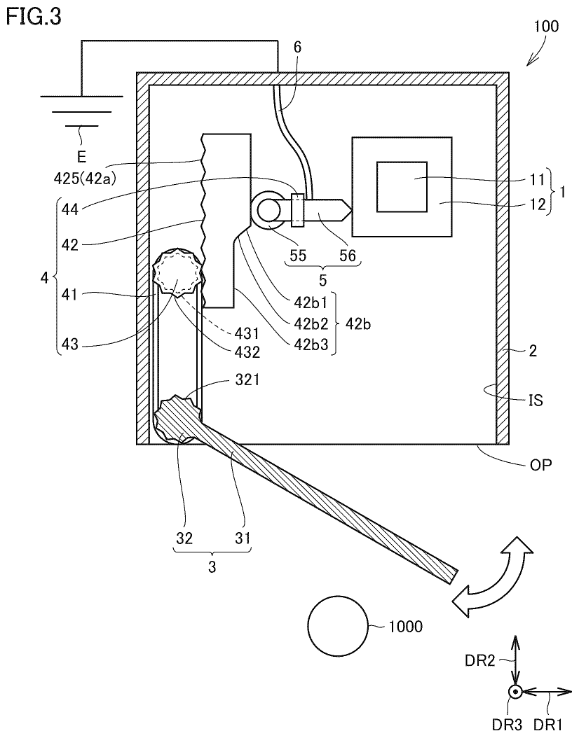

In FIGS. 1 and 2, ground wire 6 and ground E are electrically connected to two different faces of housing 2. However, as illustrated in FIG. 3, ground wire 6 and ground E may be electrically connected to housing 2 so as to sandwich one face of housing 2.

Subsequently, actions and effects of the present embodiment will be described.

In power conversion device 100 according to the first embodiment, as illustrated in FIGS. 1 and 2, movable portion 5 is configured to be detachable with respect to power converter 1. As illustrated in FIG. 1, power converter 1 is configured to be grounded via movable portion 5 in the open state of door 3. Therefore, power converter 1 can be grounded in the open state of door 3. As a result, in the open state of door 3, worker 1000 can safely perform work on power converter 1. Therefore, a safe working environment can be provided.

As illustrated in FIG. 2, power converter 1 is configured to be disposed with a gap from movable portion 5 in the closed state of door 3. Therefore, power converter 1 can be electrically shut off in the closed state of door 3. As a result, in the closed state of door 3, it is possible to suppress high-frequency noise generated from power converter 1 from flowing out from power converter 1 to ground E via housing 2. When the high-frequency noise flows out to ground E, the high-frequency noise having flowed out becomes a common mode noise. In the present embodiment, since the high-frequency noise can be suppressed from flowing out to ground E, the common mode noise can be suppressed.

As illustrated in FIG. 1, metal member 12 is a cooler. Therefore, the semiconductor element 11 of power converter 1 can be cooled.

As illustrated in FIG. 1, transmission portion 4 is configured to transmit the rotational movement of door 3 to movable portion 5 so as to attach and detach movable portion 5 to and from power converter 1. Therefore, movable portion 5 operates by rotational energy applied to door 3 by worker 1000. In other words, movable portion 5 operates by a manual operation of worker 1000. Therefore, it is not necessary to supply power from the outside to move movable portion 5. Therefore, movable portion 5 can be attached and detached to and from power converter 1 even in a situation where power is not supplied, for example, at a time of a power failure.

Since movable portion 5 operates by a manual operation of worker 1000, regardless of the operating state of power converter 1, opening of door 3 by worker 1000 can make power converter 1 be grounded in the open state of door 3.

Since movable portion 5 is manually operated by worker 1000, it is not necessary to supply power to movable portion 5. Therefore, no electronic component is necessary for movable portion 5 to operate. Therefore, durability of movable portion 5 is improved as compared with a case where an electronic component is used. As a result, reliability of power conversion device 100 is improved.

As illustrated in FIG. 1, moving portion 42 is a plane cam. Therefore, a plane cam can be used as moving portion 42 of transmission portion 4.

As illustrated in FIG. 1, movable portion 5 and transmission portion 4 are connected to housing 2. Therefore, it is possible to prevent movable portion 5 and transmission portion 4 from disturbing an approaching path from opening OP to power converter 1 as compared with a case where movable portion 5 and transmission portion 4 are connected to door 3. In addition, a work area, for work, between door 3 and opening OP can be made large. Therefore, workability of worker 1000 with respect to power converter 1 is improved. When movable portion 5 and transmission portion 4 are installed on the deep side of housing 2 as viewed from worker 1000, the workability is further improved.

As illustrated in FIG. 3, ground wire 6 and ground E may be electrically connected to housing 2 so as to sandwich one face of housing 2. In this case, a ground path between power converter 1 and ground E can be made shorter as compared with a case where ground wire 6 and ground E do not sandwich one face of housing 2. Therefore, a parasitic inductance of the ground path can be reduced. Therefore, grounding of power converter 1 is stabilized.

### Second Embodiment

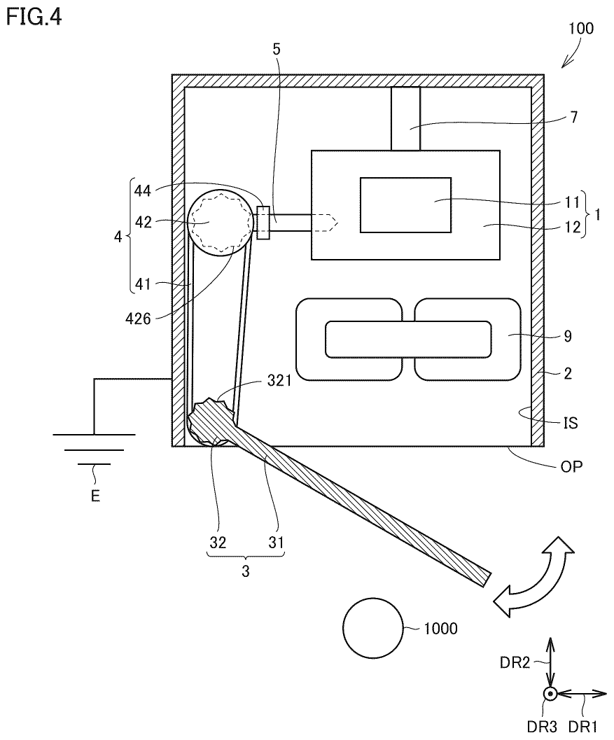

Next, with reference to FIGS. 4 to 6, a configuration of a power conversion device 100 according to a second embodiment will be described. The second embodiment has the same configuration, actions, and effects as the first embodiment described above unless otherwise specified. Therefore, the same components as in the first embodiment are denoted by the same reference signs, and the description thereof will not be repeated.

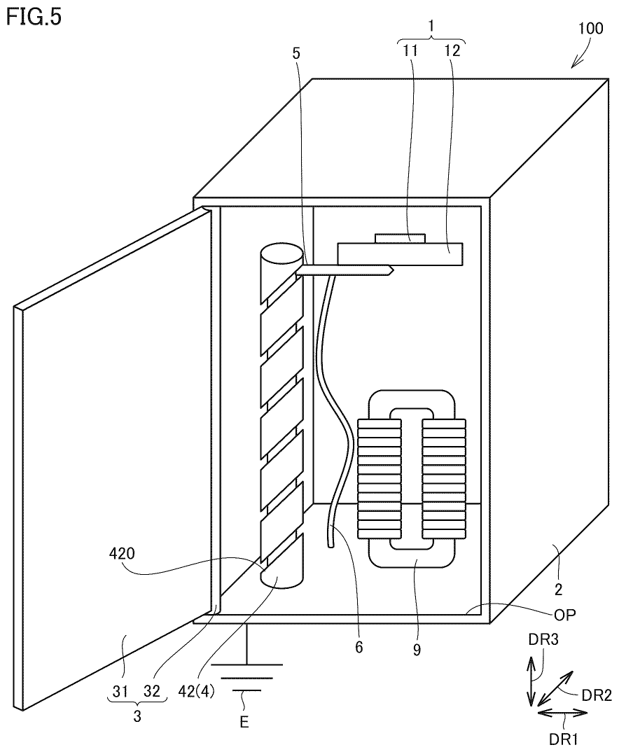

As illustrated in FIG. 4, a transmission portion 4 of power conversion device 100 according to the present embodiment includes a connection portion 41, a moving portion 42, a restriction portion 44. As illustrated in FIG. 5, moving portion 42 is a solid cam. Specifically, moving portion 42 is a cylindrical cam, which is one type of solid cam. A groove 420 is provided in an outer periphery of moving portion 42. Groove 420 is spirally provided in the outer periphery of moving portion 42. Movable portion 5 is engaged with groove 420 of moving portion 42.

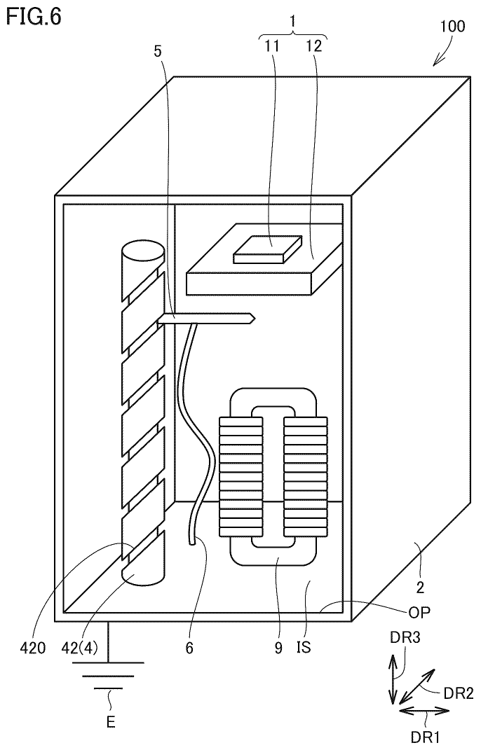

In FIG. 5, for convenience of description, power converter 1, movable portion 5, and groove 420 are illustrated in a planar manner. In FIGS. 5 and 6, connection portion 41 (see FIG. 4) and restriction portion 44 (see FIG. 4) are not illustrated for convenience of description. In FIG. 6, door 3 is not illustrated for convenience of description. In FIG. 6, for convenience of explanation, movable portion 5 and groove 420 are illustrated in a planar manner.

In the present embodiment, moving portion 42 includes a fifth gear part 426. Connection portion 41 is engaged with fifth gear part 426 of moving portion 42. More specifically, engaged portions between the chains of connection portion 41 mesh with fifth gear part 426. Moving portion 42 is configured to rotate by a rotational movement of door 3 transmitted by connection portion 41.

A movement of movable portion 5 along the Y-axis direction DR2 is restricted by restriction portion 44. Therefore, movable portion 5 is configured not to rotate by rotation of moving portion 42. Movable portion 5 is configured to linearly move along a rotation axis direction (Z-axis direction DR3) of moving portion 42 by the rotation of moving portion 42. As illustrated in FIGS. 5 and 6, moving portion 42 is configured to linearly move movable portion 5 engaged with groove 420 of moving portion 42, along the Z-axis direction DR3.

Power conversion device 100 may further include a reactor 9. For example, when power conversion device 100 is included in an uninterruptible power supply, reactor 9, which is a heavy object, may be disposed on a lower side in housing 2, and power converter 1 may be disposed on an upper side in housing 2. In FIGS. 5 and 6, reactor 9 is illustrated in a planar manner for convenience of description.

Next, an operation of power conversion device 100 according to the second embodiment will be described.

As illustrated in FIG. 4, when door 3 is switched from the open state of door 3 to the closed state of door 3, shaft portion 32 rotates counterclockwise. Therefore, when door 3 is switched from the open state of door 3 to the closed state of door 3, moving portion 42 rotates counterclockwise. However, when door 3 is switched from the open state of door 3 to the closed state of door 3, shaft portion 32 and moving portion 42 may rotate clockwise.

As illustrated in FIGS. 5 and 6, when door 3 is switched from the open state of door 3 to the closed state of door 3, transmission portion 4 transmits the rotational movement of door 3 to movable portion 5, so that movable portion 5 moves, along the Z-axis direction DR3, away from power converter 1. Specifically, movable portion 5 moves downward. As a result, movable portion 5 comes apart from power converter 1. In other words, power converter 1 is electrically shut off from movable portion 5.

As illustrated in FIG. 4, when door 3 is switched from the closed state of door 3 to the open state of door 3, shaft portion 32 rotates reversely to a rotation direction at a time of door 3 being switched from the open state to the closed state. As a result, when door 3 is switched from the closed state of door 3 to the open state of door 3, moving portion 42 rotates reversely to a rotation direction at a time of door 3 being switched from the open state to the closed state. In FIG. 4, shaft portion 32 and moving portion 42 rotate clockwise.

As illustrated in FIGS. 5 and 6, when door 3 is switched from the closed state of door 3 to the open state of door 3, transmission portion 4 transmits the rotational movement of door 3 to movable portion 5, so that movable portion 5 moves, along the Z-axis direction DR3, closer to power converter 1. Specifically, movable portion 5 moves upward. As a result, movable portion 5 comes into contact with power converter 1. Therefore, power converter 1 is grounded via housing 2 and movable portion 5.

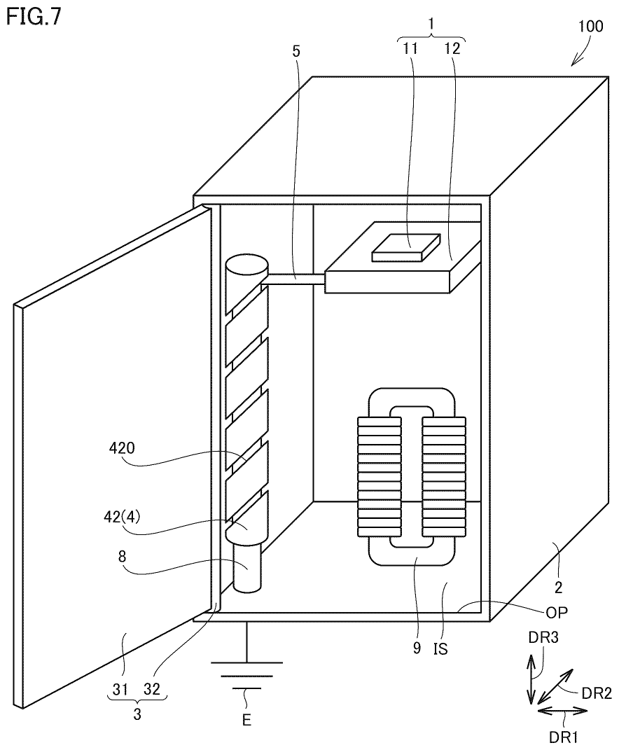

Next, with reference to FIG. 7, a configuration of a variation of a power conversion device 100 according to the second embodiment will be described.

With reference to FIGS. 5 and 6, movable portion 5 is electrically connected to housing 2 with ground wire 6. On the other hand, in the variation of the second embodiment, as illustrated in FIG. 7, power conversion device 100 does not include ground wire 6 that electrically connects movable portion 5 and housing 2. Noe that, in FIG. 7, groove 420 and reactor 9 are illustrated in a planar manner for convenience of description.

A material of moving portion 42 is metal. Moving portion 42 is electrically connected to housing 2. Moving portion 42 is electrically connected to a bottom portion of housing 2. Specifically, moving portion 42 may be electrically connected to housing 2 by a conductive fixture 8. Moving portion 42 is electrically connected to movable portion 5. Therefore, movable portion 5 is grounded via transmission portion 4, fixture 8, and housing 2.

Preferably, a metallic surface of moving portion 42 is conductively exposed. In this case, the surface of moving portion 42 and groove 420 need not be coated for corrosion prevention.

Subsequently, actions and effects of the present embodiment will be described.

In power conversion device 100 according to the second embodiment, as illustrated in FIG. 5, moving portion 42 is a solid cam. Therefore, a solid cam can be used as moving portion 42 of transmission portion 4.

In power conversion device 100 according to the variation of the second embodiment, as illustrated in FIG. 7, moving portion 42 is electrically connected to housing 2. Moving portion 42 is electrically connected to movable portion 5. Therefore, movable portion 5 and housing 2 need not be electrically connected by ground wire 6. As a result, ground wire 6 (see FIG. 5) need not be used. Therefore, power conversion device 100 can be simply configured.

Since ground wire 6 (see FIG. 5) need not be used, it is possible to suppress a short circuit of the wirings due to interference of ground wire 6 (see FIG. 5) with reactor 9. As a result, reliability of power conversion device 100 is improved.

### Third Embodiment

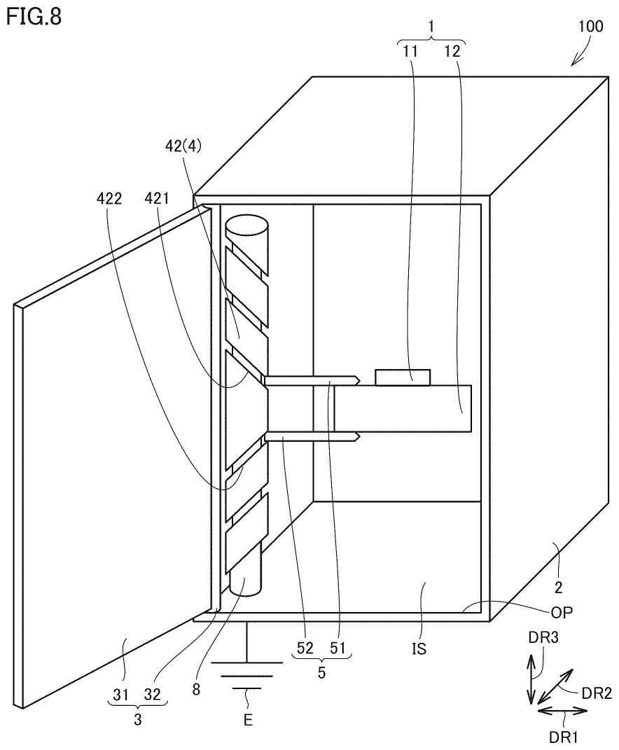

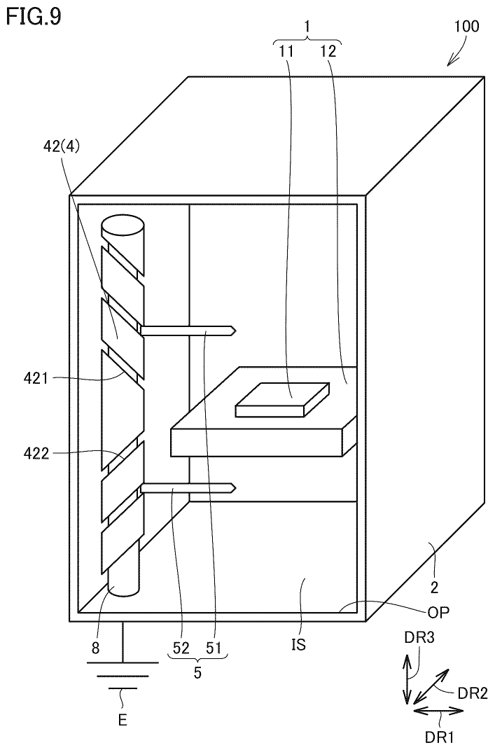

Next, with reference to FIGS. 8 and 9, a configuration of a power conversion device 100 according to a third embodiment will be described. The third embodiment has the same configuration, actions, and effects as the second embodiment described above unless otherwise specified. Therefore, the same components as in the second embodiment are denoted by the same reference signs, and the description thereof will not be repeated.

As illustrated in FIGS. 8 and 9, power conversion device 100 according to the present embodiment includes a fixture 8. In addition, power conversion device 100 does not include ground wire 6 (see FIG. 5). Movable portion 5 according to the present embodiment includes a first movable part 51 and a second movable part 52. First movable part 51 and second movable part 52 sandwich power converter 1. Specifically, first movable part 51 and second movable part 52 sandwich power converter 1 along the Z-axis direction DR3. Each of first movable part 51 and second movable part 52 is configured to be detachable with respect to power converter 1. Therefore, each of first movable part 51 and second movable part 52 is in contact with power converter 1 in the open state of door 3. Each of first movable part 51 and second movable part 52 is disposed with a gap from power converter 1 in the closed state of door 3.

In FIG. 8, power converter 1 is illustrated in a planar manner for convenience of description. In FIGS. 8 and 9, connection portion 41 (see FIG. 4) and the restriction portion 44 (see FIG. 4) are not illustrated for convenience of description. In FIGS. 8 and 9, groove 420 is illustrated in a planar manner for convenience of description. In FIG. 9, door 3 is not illustrated for convenience of description.

In the present embodiment, groove 420 of moving portion 42 includes first groove part 421 and second groove part 422. Spirals of first groove part 421 and second groove part 422 are wound opposite to each other. First movable part 51 and second movable part 52 are respectively engaged with first groove part 421 and second groove part 422. First groove part 421 and second groove part 422 are exposed.

Moving portion 42 is electrically connected to housing 2. Moving portion 42 is electrically connected to each of first movable part 51 and second movable part 52. Therefore, each of first movable part 51 and second movable part 52 is grounded via moving portion 42 and housing 2.

Preferably, power conversion device 100 according to the present embodiment does not include ground wire 6 (see FIG. 1).

Next, an operation of power conversion device 100 according to the third embodiment will be described.

When door 3 is switched from the open state of door 3 to the closed state of door 3, transmission portion 4 transmits the rotational movement of door 3 to movable portion 5, so that first movable part 51 and second movable part 52 move away from power converter 1. Specifically, first movable part 51 moves upward. Second movable part 52 moves downward. Thus, power converter 1 is electrically shut off from movable portion 5.

When door 3 is switched from the closed state of door 3 to the open state of door 3, transmission portion 4 transmits the rotational movement of door 3 to movable portion 5, so that movable portion 5 moves so as to sandwich power converter 1. Specifically, first movable part 51 comes into contact with an upper surface of metal member 12 by moving downward. Second movable part 52 comes into contact with a lower surface of metal member 12 by moving upward. As a result, movable portion 5 comes into contact with power converter 1 so as to sandwich power converter 1. Therefore, power converter 1 is grounded via movable portion 5.

Subsequently, actions and effects of the present embodiment will be described.

In power conversion device 100 according to the third embodiment, as illustrated in FIGS. 8 and 9, each of first movable part 51 and second movable part 52 is configured to be detachable with respect to power converter 1. Therefore, power converter 1 can be electrically connected in parallel to ground E by respective ones of first movable part 51 and second movable part 52. As a result, it is possible to reduce an impedance from power converter 1 to ground E. Therefore, grounding of power converter 1 is stable.

Since power converter 1 can be electrically connected to ground E by each of first movable part 51 and second movable part 52, electrical connection between power converter 1 and ground E can be made more redundant than when power converter 1 is electrically connected to ground E by only one movable portion. Therefore, reliability of power conversion device 100 is improved.

### Fourth Embodiment

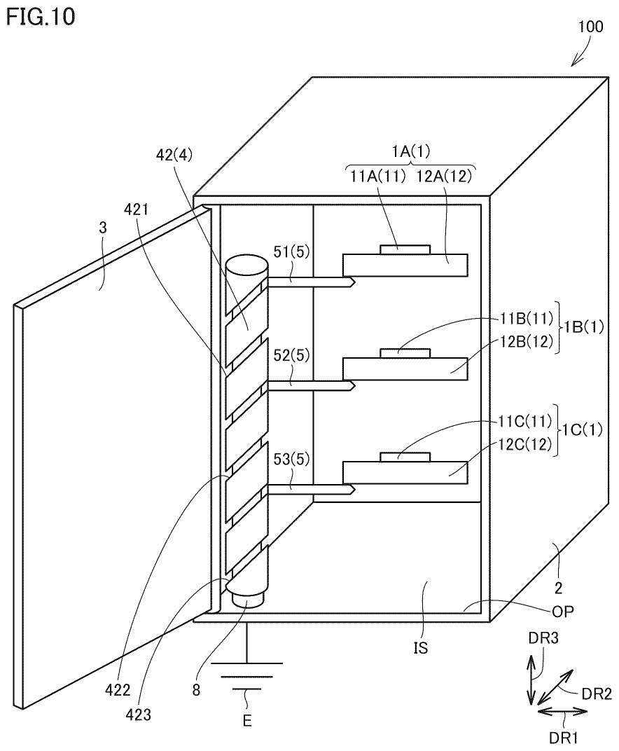

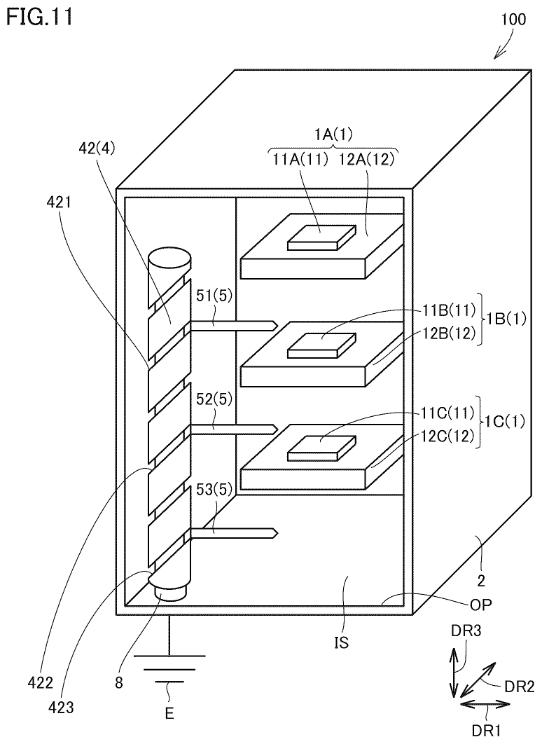

Next, with reference to FIGS. 10 and 11, a configuration of a power conversion device 100 according to a fourth embodiment will be described. The fourth embodiment has the same configuration, actions, and effects as the third embodiment described above unless otherwise specified. Therefore, the same components as in the third embodiment are denoted by the same reference signs, and the description thereof will not be repeated.

As illustrated in FIGS. 10 and 11, power converter 1 includes a first power conversion part 1A, a second power conversion part 1B, and a third power conversion part 1C. Therefore, power converter 1 is configured as a modular power converter. Power converter 1 is included in, for example, a modular uninterruptible power supply. first power conversion part 1A, second power conversion part 1B, and third power conversion part 1C are disposed in order from the upper side along the Z-axis direction DR3.

For convenience of description, power converter 1 is illustrated in a planar manner in FIG. 10. In FIGS. 10 and 11, connection portion 41 (see FIG. 4) and restriction portion 44 see (see FIG. 4) are not illustrated for convenience of description. In FIGS. 10 and 11, groove 420 is illustrated in a planar manner for convenience of description. In FIG. 11, door 3 is not illustrated for convenience of description.

In modular power converter 1, preferably, power capacities of first power conversion part 1A, second power conversion part 1B, and third power conversion part 1C are equal to each other. In modular power converter 1, the overall power capacity of power converter 1 is adjusted by the power capacities of a plurality of power conversion parts (first power conversion part 1A to third power conversion part 1C). In addition, first power conversion part 1A, second power conversion part 1B, and third power conversion part 1C may be each configured to convert one of currents of three different phases of three-phase currents.

first power conversion part 1A includes a first semiconductor portion 11A and a first metal portion 12A. First metal portion 12A is connected to first semiconductor portion 11A. second power conversion part 1B includes a second semiconductor portion 11B and a second metal portion 12B. Second metal portion 12B is connected to second semiconductor portion 11B. third power conversion part 1C includes a third semiconductor portion 11C and a third metal portion 12C. Third metal portion 12C is connected to third semiconductor portion 11C. First metal portion 12A, second metal portion 12B, and third metal portion 12C are each configured as a cooler.

Movable portion 5 includes a first movable part 51, a second movable part 52, and a third movable part 53. First movable part 51, second movable part 52, and third movable part 53 are disposed in order from the upper side along the Z-axis direction DR3. First movable part 51 is configured to be detachable with respect to first power conversion part 1A. Second movable part 52 is configured to be detachable with respect to second power conversion part 1B. Third movable part 53 is configured to be detachable with respect to third power conversion part 1C. Therefore, first movable part 51, second movable part 52, and third movable part 53 are respectively configured to be in contact with first power conversion part 1A, second power conversion part 1B, and third power conversion part 1C in the open state of door 3. First movable part 51, second movable part 52, and third movable part 53 are respectively configured to be disposed, each with a gap, from first power conversion part 1A, second power conversion part 1B, and third power conversion part 1C in the closed state of door 3.

Groove 420 of moving portion 42 includes a first groove part 421, a second groove part 422, and a third groove part 423. First groove part 421, second groove part 422, and third groove part 423 are disposed in this order from the upper side along the Z-axis direction DR3. First movable part 51, second movable part 52, and third movable part 53 are respectively engaged with first groove part 421, second groove part 422, and third groove part 423.

Next, an operation of power conversion device 100 according to the fourth embodiment will be described.

When door 3 is switched from the open state of door 3 to the closed state of door 3, transmission portion 4 transmits the rotational movement of door 3 to first movable part 51, second movable part 52, and third movable part 53, so that first movable part 51, second movable part 52, and third movable part 53 move downward. As a result, first movable part 51, second movable part 52, and third movable part 53 are disposed each with a gap from first power conversion part 1A, second power conversion part 1B, and third power conversion part 1C. Therefore, first power conversion part 1A, second power conversion part 1B, and third power conversion part 1C are respectively electrically shut off from first movable part 51, second movable part 52, and third movable part 53.

When door 3 is switched from the closed state of door 3 to the open state of door 3, transmission portion 4 transmits the rotational movement of door 3 to first movable part 51, second movable part 52, and third movable part 53, so that first movable part 51, second movable part 52, and third movable part 53 move upward. As a result, first movable part 51, second movable part 52, and third movable part 53 respectively come into contact with lower surfaces of first power conversion part 1A, second power conversion part 1B, and third power conversion part 1C. Therefore, first power conversion part 1A, second power conversion part 1B, and third power conversion part 1C are respectively grounded via first movable part 51, second movable part 52, and third movable part 53.

Subsequently, actions and effects of the present embodiment will be described.

In power conversion device 100 according to the fourth embodiment, as illustrated in FIGS. 10 and 11, first movable part 51 is configured to be detachable with respect to first power conversion part 1A. Second movable part 52 is configured to be detachable with respect to second power conversion part 1B. Therefore, even when power converter 1 is a modular power converter 1 including a first power conversion part 1A and a second power conversion part 1B, it is possible to switch between grounding and electrical shut-off in accordance with the open state of door 3 and the closed state of door 3.

It should be understood that the embodiments disclosed herein are illustrative in all respects and are not restrictive. The scope of the present disclosure is defined not by the above description but by the claims, and is intended to include meanings equivalent to the claims and all modifications within the scope.

### REFERENCE SIGNS LIST

1: power converter, 1A: first power conversion part, 1B: second power conversion part, 2: housing, 3: door, 4: transmission portion, 5: movable portion, 51: first movable part, 52: second movable part, 11: semiconductor element, 12: metal member, 32: shaft portion, 41: connection portion, 42: moving portion, 100: power conversion device, IS: internal space, OP: opening

1. A power conversion device comprising:
a housing, the housing including:
an opening; and
an internal space communicating with the opening;
a door connected to the housing;
a power converter disposed in the internal space with a gap from the housing; and
a movable portion disposed in the internal space to be attached and detached to and from the power converter,
wherein the door is configured to be switched between an open state in which the opening is open and a closed state in which the opening is closed, and
the power converter is configured to be grounded via the movable portion in the open state of the door, and is configured to be disposed with a gap from the movable portion in the closed state of the door.

2. The power conversion device according to claim 1, wherein the power converter includes:
a semiconductor element; and
a metal member connected to the semiconductor element,
the movable portion is configured to be attached and detached to and from the metal member of the power converter, and
the metal member is a cooler.

3. The power conversion device according to claim 1, further comprising a transmission portion,
wherein the door is configured to rotationally move with respect to the housing to switch between the open state and the closed state, and
the transmission portion is configured to transmit a rotational movement of the door to the movable portion to attach and detach the movable portion to and from the power converter.

4. The power conversion device according to claim 3, wherein the transmission portion is configured to convert the rotational movement of the door into a linear movement, and is configured to transmit the linear movement to the movable portion to linearly move the movable portion.

5. The power conversion device according to claim 4, wherein the door includes a shaft portion configured as a rotation axis of the rotational movement, the transmission portion includes:
a connection portion connected to the shaft portion; and
a moving portion to linearly move the movable portion by the rotational movement transmitted by the connection portion, and
the moving portion is a plane cam.

6. The power conversion device according to claim 4, wherein the door includes a shaft portion configured as a rotation axis of the rotational movement, the transmission portion includes:
a connection portion connected to the shaft portion; and
a moving portion to linearly move the movable portion by the rotational movement transmitted by the connection portion, and
the moving portion is a solid cam.

7. The power conversion device according to claim 3, wherein the movable portion and the transmission portion are connected to the housing.

8. The power conversion device according to claim 1, wherein the movable portion includes a first movable part and a second movable part, and
each of the first movable part and the second movable part is configured to be attached and detached to and from the power converter.

9. The power conversion device according to claim 8, wherein the power converter includes a first power conversion part and a second power conversion part, the first movable part is configured to be attached and detached to and from the first power conversion part, and
the second movable part is configured to be attached and detached to and from the second power conversion part.
